(19) United States
(12) Patent Application Publication
(10) Pub. No.: US 2018/0287000 A1
(43) Pub. Date: Oct. 4, 2018

(54) PARABOLIC CONCENTRATOR INTEGRATED WITH BALL LENS

(71) Applicant: The Regents of the University of Michigan, Ann Arbor, MI (US)

(72) Inventors: Stephen R. FORREST, Ann Arbor, MI (US); Kyusang LEE, Ann Arbor, MI (US); Byungjun LEE, Ann Arbor, MI (US)

(21) Appl. No.: 15/772,241

(22) PCT Filed: Nov. 2, 2016
(86) PCT No.: PCT/US2016/060034

§ 371 Date: Apr. 30, 2018

Related U.S. Application Data
(60) Provisional application No. 62/249,915, filed on Nov. 2, 2015.
(60) Provisional application No. 62/299,062, filed on Feb. 24, 2016.

(51) Int. Cl. H01L 31/054; H01L 31/18; G02B 19/00

(52) U.S. Cl. CPC H01L 31/0547; H01L 31/0543; G02B 19/0028; G02B 19/0042; H01L 31/18

(57) ABSTRACT

A solar concentrator apparatus for harnessing solar flux is disclosed. The solar concentrator apparatus has a parabolic body having a reflecting surface to receive incident light. The parabolic body and reflecting surface have an incident light flux cone, and a ball lens is positioned within at least a portion of the incident light flux cone. The ball lens has a refracted area and is configured to direct at least a portion of the incident light that is reflected by the reflecting surface of the parabolic body into the refracted area.

This application claims priority to U.S. Provisional Application No. 62/249,915, filed Nov. 2, 2015 and U.S. Provisional Application No. 62/299,062 filed Feb. 24, 2016, which are incorporated herein by reference in entirety.

The subject matter of the present disclosure was made by, on behalf of, and/or in connection with one or more of the following parties to a joint university-corporation research agreement: The Regents of the University of Michigan and NanoFlex Power Corporation. The agreement was in effect on and before the date the subject matter of the present disclosure was prepared, and was made as a result of activities undertaken within the scope of the agreement.

The present disclosure generally relates to solar concentrators, and particularly, to solar concentrators integrated with ball lenses.

Cost-effective solar to electrical power conversion is one of the key issues for photovoltaic technologies. Concentrating the suns energy at discrete locations may be advantageous, as fewer photovoltaic modules are required to generate a given electrical advantage. Solar concentrators can both reduce the overall cost and enhance the performance of a given photovoltaic module by concentrating sunlight into a smaller area with greater intensity. This may reduce the expense associated with photovoltaic module manufacturing and increase the performance of a photovoltaic module by increased light intensity.

Parabolic concentrators may achieve a high concentration factor by concentrating the incident sunlight into a corresponding to the parabolic shape of the concentrator. However, due to the parabolic shape of the concentrator, incident light that is off-angle of the parabolic concentrator axis cannot be harvested at the focal point.

Moreover, existing parabolic concentrators may have a very narrow acceptance angle. Further, existing parabolic concentrators with a narrow acceptance angle may require a complex and precisely shaped reflector that necessitates expensive materials to ensure proper reflectance properties. Additionally, expensive and burdensome solar tracking systems may be required to track the motion of the sun in order to compensate for the narrow acceptance angle. Presently, parabolic concentrators with narrow acceptance angles are only efficient in the select instances in which they are combined with complex tracking systems.

The present disclosure addresses one or more of the problems set forth above and/or other problems associated with conventional narrow acceptance angle solar concentrators.

The disclosed embodiments relate to solar concentrator apparatuses with high concentrator factors. In one aspect of the present disclosure, a solar concentrator apparatus comprises a parabolic body having a reflecting surface to receive incident light; wherein the parabolic body and reflecting surface have an incident light flux cone; and a ball lens positioned within at least a portion of the incident light flux cone, wherein the ball lens has a corresponding refracted area and is configured to direct at least a portion of the incident light that is reflected by the reflecting surface of the parabolic body into the refracted area.

In another aspect, a method of manufacturing a parabolic solar concentrator and lens pair comprises forming a concentrator body with a corresponding incident light flux cone, coating a reflecting surface to the concentrator body, forming a lens with a corresponding refracted area, positioning at least a portion of the lens within the incident light flux cone; and, positioning at least a portion of at least one photovoltaic module within the refracted area.

In a further aspect, a compound parabolic concentrator apparatus comprises a compound parabolic concentrator body having a reflecting surface, a spherical ball lens positioned within a base region of the compound parabolic concentrator body, and at least one photovoltaic module positioned beneath the spherical ball lens.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate disclosed embodiments and, together with the description, serve to explain the disclosed embodiments. In the drawings:

FIG. 1 is a profile view of a solar concentrator apparatus, consistent with disclosed embodiments;

FIG. 1B is a profile view of the solar concentrator apparatus of FIG. 1 with a photovoltaic module;

FIG. 2 is a profile view of another solar concentrator apparatus, consistent with disclosed embodiments;

FIG. 3A is a conceptual illustration of a zero-degree incident light interaction with a parabolic reflecting surface;

FIG. 3B is a conceptual illustration of a nonzero-degree incident light interaction with a parabolic reflecting surface;

FIGS. 4A and 4B are conceptual illustrations of nonzero-degree incident light interactions without and with a ball lens, respectively;

FIG. 5 is a conceptual illustration of the relationship between components of a solar concentrator apparatus;

FIG. 6 is a conceptual illustration of the ball lens of FIG. 5;

FIGS. 7A and 7B illustrate a zero-degree incident light and a nonzero-degree incident light interaction with a spherical ball lens;

FIG. 8 is a graph that illustrates a relationship between the incident angle of solar flux and the incident power of a solar concentrator apparatus with a ball lens angle of 135°;

FIG. 9 is a graph that illustrates a relationship between the incident angle of solar flux and the incident power of three solar concentrator apparatuses;

FIG. 10 is a graph that illustrates a relationship between the incident angle of solar flux and the incident power of seven solar concentrator apparatuses in which the ball lens is positioned within varying locations;

FIG. 11 is a graph that illustrates a relationship between the incident angle of solar flux and the incident power of seven solar concentrator apparatuses in which the ball lens has varying ball lens angles;

FIG. 12 is a graph that illustrates the incident power of five similar solar concentrator apparatuses with various ball lens surface coatings;

FIGS. 13A and 13B illustrate the incident power of similar solar concentrator apparatuses but with varying parabolic angles;

FIGS. 14A and 14B illustrate the incident power of similar solar concentrator apparatuses but with varying ball lens angles and ball lens surface coatings;

FIG. 15 is an exemplary flowchart of a method of manufacture of a solar concentrator apparatus;

FIGS. 16A and 16B are elevation views of compound solar concentrator apparatuses with and without a hemispherical ball lens, respectively;

FIG. 17 is a graph that illustrates the energy harvesting potential of various compound solar concentrator apparatuses; and

FIG. 18 is a graph that illustrates the concentration factor of compound parabolic concentrators with and without a hemispherical ball lens, respectively.

Reference will now be made in detail to the disclosed embodiments, examples of which are illustrated in the accompanying drawings. Wherever convenient, the same reference numbers will be used throughout the drawings to refer to the same or like parts.

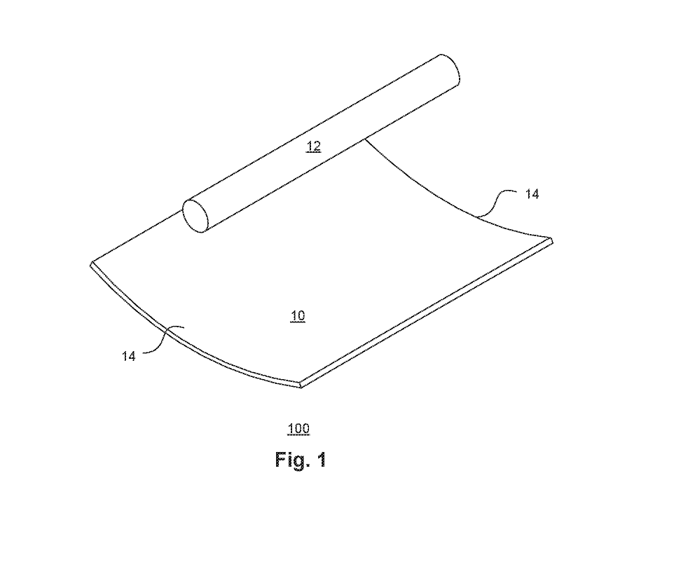

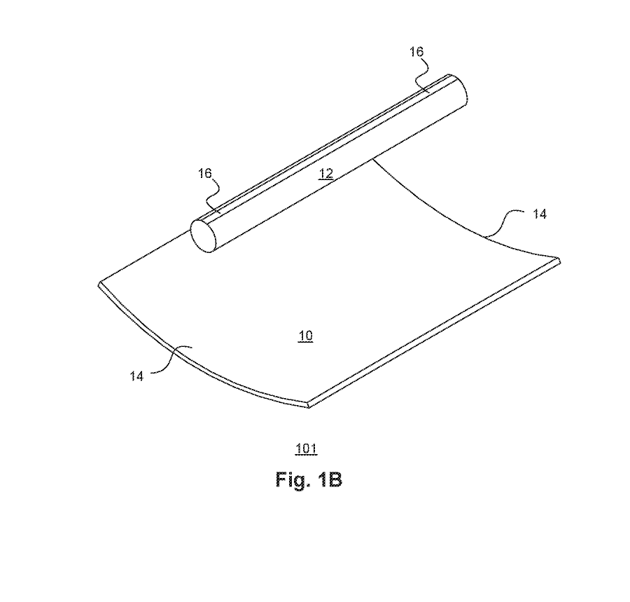

FIG. 1 is a profile view of a solar concentrator apparatus. The exemplary linear solar concentrator apparatus 100 is illustrated with a trough parabolic body 10 and a cylindrical ball lens 12. The trough parabolic body 10 has a reflecting surface 14 that is highly reflective. For example, the reflective surface may have a smooth finished silver surface.

Moreover, the reflecting surface 14 may be a surface of the trough parabolic body 10 or it may be a surface coating. For example, a reflecting film may be deposited to the trough parabolic body 10. Furthermore, in at least one embodiment a passivation layer may be applied to the reflecting surface 14. The passivation layer may be a transparent, wide bandgap material. For example, a silicon oxide passivation layer may be applied to a silver reflecting surface 14 to prevent the silver of the reflecting surface 14 from oxidizing. This may be advantageous because when silver oxidizes it is less reflective.

In the exemplary embodiment, a cylindrical ball lens 12 is illustrated above the trough parabolic body 10. The trough parabolic body 10 may cast (reflect) light into a first incident light flux cone above the centerline of the major axis of the trough parabolic body 10 terminating into focal point. The cylindrical ball lens 12 may be positioned, at least partially, within the incident light flux cone.

FIG. 1B is a profile view of the solar concentrator apparatus of FIG. 1 with a photovoltaic module. In the exemplary embodiment, the photovoltaic module 16 is above and in contact with the cylindrical ball lens 12. The trough parabolic body 10 and the reflecting surface 14 may concentrate solar energy into a first linear focal plane that coincides, at least partially, with the location of the cylindrical ball lens 12 and the photovoltaic module 16.

Moreover, the cylindrical ball lens 12 may concentrate the solar energy of the incident light flux cone into a refracted area that coincides, at least partially, with the active surface of the photovoltaic module 16. An active surface of a photovoltaic module 16 may be commonly understood as a surface of a photovoltaic module 16 that is designed to receive solar flux. Further, it should be understood that an active surface need not be planar but it may be in some embodiments.

In at least one exemplary embodiment, (not illustrated) the photovoltaic module 16 and cylindrical ball lens 12 may be supported in place with structural supports. The structural supports may be plastic rods or sidewall supports coupled to the trough parabolic body 10 and the cylindrical ball lens 12. The photovoltaic module 16 may be adhered to or in contact with the cylindrical ball lens 12. Further, the structural supports may be transparent in order to minimize light loss. Moreover, it should be understood that the particular structural reinforcement employed may be any type of structural reinforcement such that the cylindrical ball lens 12 and photovoltaic module 16 are adequately suspended above the trough parabolic body 10.

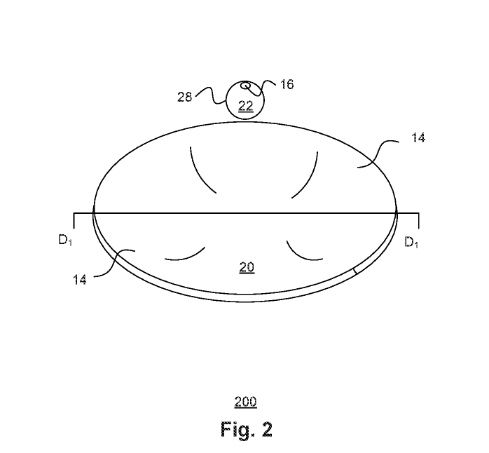

FIG. 2 is a profile view of another solar concentrator apparatus. In the exemplary embodiment, the solar concentrator apparatus 200 has a dish parabolic body 20 and a spherical ball lens 22. The dish parabolic body 20 has a parabolic body diameter D₁. Further, the solar concentrator apparatus 200 has a reflecting surface 14 that may be similar to the reflecting surface 14 of the embodiments of FIGS. 1A and 1B.

In the exemplary embodiment, a spherical ball lens 22 is illustrated above the dish parabolic body 20. The dish parabolic body 20 may cast (reflect) light into an incident light flux cone above the center of the dish parabolic body 20. The spherical ball lens 22 may be positioned, at least partially, within the incident light flux cone and a photovoltaic module 16 may be positioned above the spherical ball lens 22.

The spherical ball lens 22 may be formed from silica, silicon, silicon dioxide, or any substantially similar chemical composition. For example, a crystalline silica such as sand or quartz. However, the spherical ball lens 22 should not be construed as limited to compositions of silica or compositions of only silica. In other embodiments, the spherical ball lens 22 may be formed from an acrylic compound. Further, the spherical ball lens 22 may have a surface coating 28. In at least one embodiment, the surface coating 28 may be formed from magnesium fluoride or any substantially similar chemical composition. Moreover, the spherical ball lens 22 may concentrate the solar energy of the incident light flux cone into a refracted area that coincides, at least partially, with the active surface of the photovoltaic module 16.

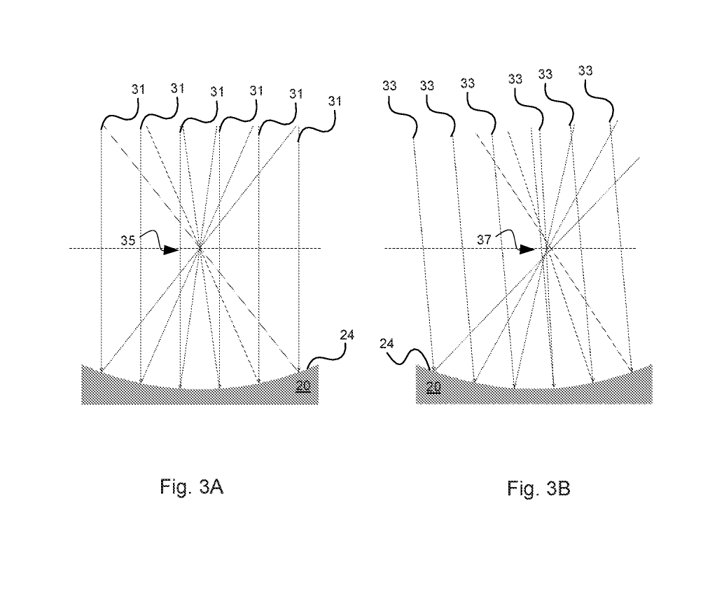

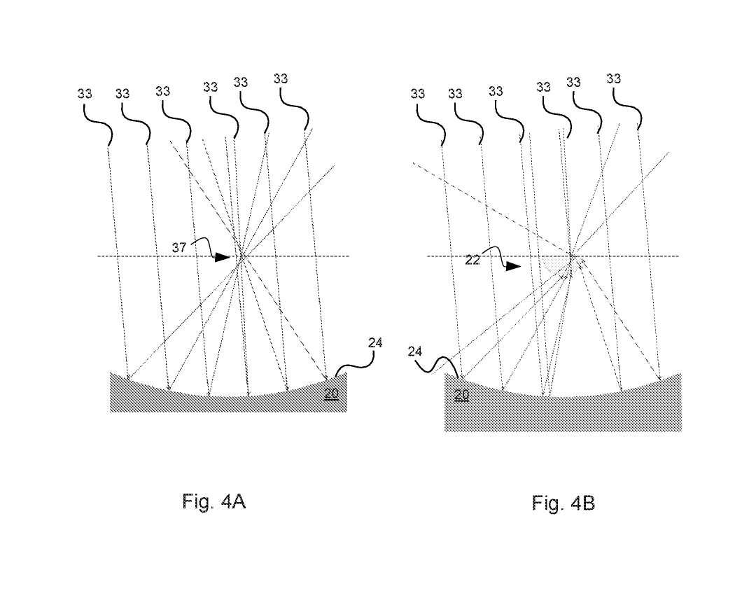

FIG. 3A is a conceptual illustration of zero-degree incident light on a parabolic reflecting surface. The conceptual illustration may be similar to, for example, the solar concentrator apparatus 200 of FIG. 2. In FIG. 3A a dish parabolic body 20 reflects zero-degree incident light 31 to a focal point 35. Zero degree incident light 31 may be defined as light that is, at least substantially, perpendicular to the parabolic body diameter D₁ (see FIG. 2) of a parabolic concentrator such as a dish parabolic body 20.

FIG. 3B is a conceptual illustration of a nonzero-degree incident light on a parabolic reflecting surface. The conceptual illustration may be similar to, for example, the solar concentrator apparatus 200 of FIG. 2. In FIG. 3B a dish parabolic body 20 reflects nonzero-degree incident light 33 into a non-uniform focal area 37. Nonzero-degree incident light may be defined as light that is, at least marginally, non-perpendicular to the parabolic body diameter D₁ (see FIG. 2) of a parabolic concentrator such as a dish parabolic body 20. Further, the incident angle of a particular nonzero-degree incident light may be defined as the angle between a zero-degree incident light 31 and the particular nonzero-degree incident light in question.

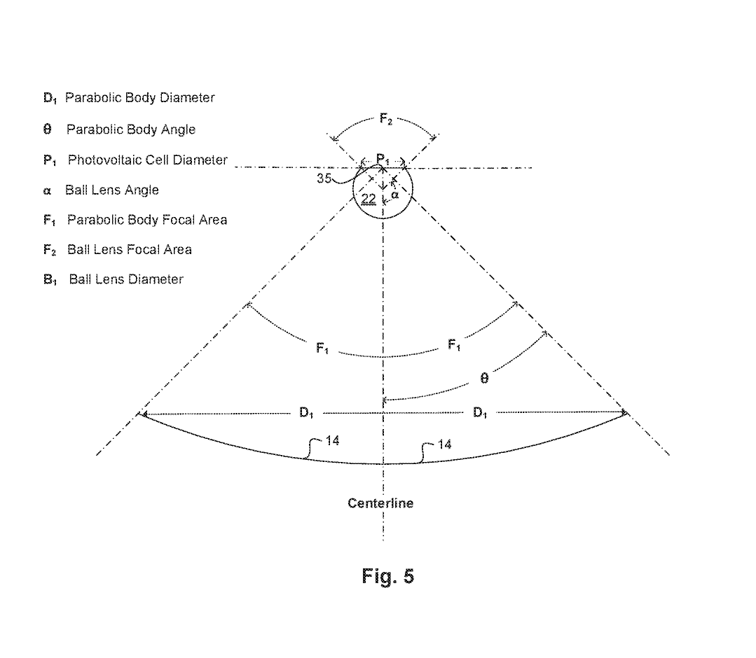

FIGS. 4A and 4B are conceptual illustrations of nonzero-degree incident light on a parabolic reflecting surface without and with a ball lens, respectively. The conceptual illustrations may be similar to, for example, the solar concentrator apparatus 200 of FIG. 2. In FIGS. 4A and 4B, a dish parabolic body 20 reflects nonzero-degree incident light 33 into a non-uniform focal area 37. However, in FIG. 4B a spherical ball lens 22 refracts the light of the non-uniform focal area 37. The refracted light may be concentrated and oriented towards a photovoltaic module 16 (see FIG. 2) that is directly above and in contact with the spherical ball lens 22.

In this way, FIG. 4B illustrates that a spherical ball lens 22, or any other similar lens, may beneficially refract the light of the non-uniform focal area 37 by re-orienting the light back towards a photovoltaic module 16 (see FIG. 2). For example, at some nonzero-degree incident light, at least a portion of the light of the non-uniform focal area 37 may not be cast onto the active surface of a photovoltaic module without the added benefit of the spherical ball lens 22. Therefore, a spherical ball lens 22 may increase the efficiency and solar harvesting potential of parabolic concentrators generally when a nonzero-degree incident light is reflected into a resultant non-uniform focal area 37.

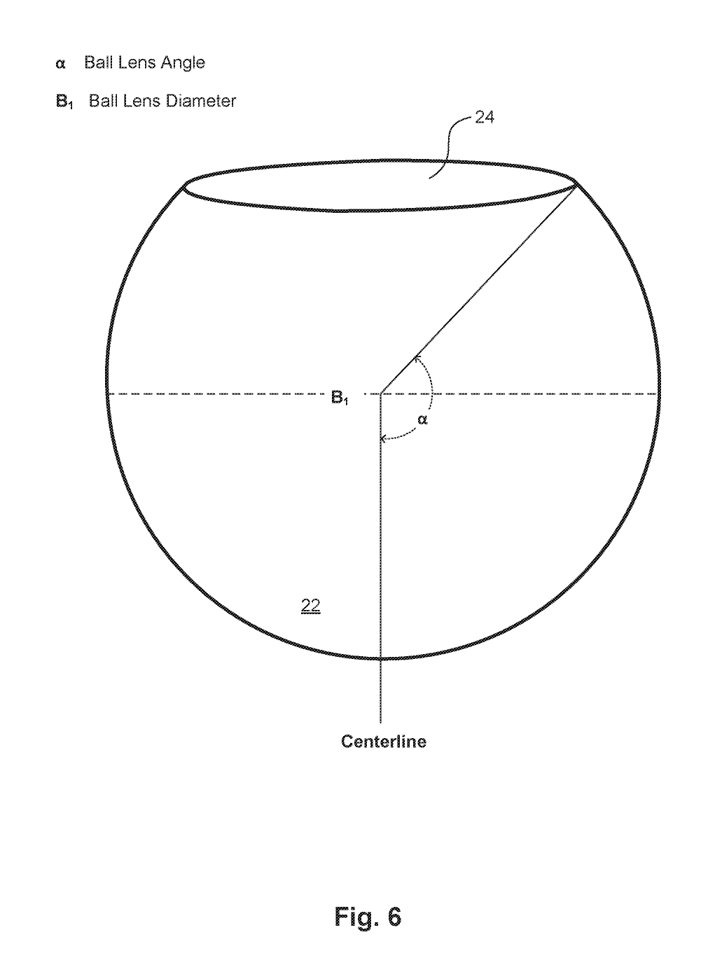

FIG. 5 is a conceptual illustration of the relationship between components of an exemplary solar concentrator apparatus. In FIG. 5 a parabolic concentrator with a reflecting surface 14 and a parabolic body diameter D₁ is illustrated. In some embodiments, the parabolic concentrator may have a trough parabolic body 10 (see FIG. 2) or a dish parabolic body 20 (see FIG. 3). Furthermore, an interaction between light reflecting from the reflecting surface 14 and a spherical ball lens 22 is illustrated. The parabolic body diameter D₁ may be similar to, for example, the diameter of the dish shaped body 20 in FIG. 2. Likewise, the spherical ball lens 22 may be similar to, for example, the spherical ball lens 22 of FIG. 2. However, other parabolic body shapes and ball lens shapes (see FIG. 1) may be conceptually understood by the principles illustrated in FIG. 5 and disclosed throughout this application.

The exemplary solar concentrator apparatus has a parabolic body angle θ and a parabolic incident light flux cone F₁. The parabolic incident light flux cone F₁ may be defined as the cone shaped region bound by broken lines, the reflecting surface 14, the end points of the parabolic body diameter D₁, and the focal point 35. The parabolic incident light flux cone F₁ may conceptually be understood as two equally sized regions broken by an imaginary centerline that projects through the focal point 35 and the midpoint of the parabolic body diameter D₁.

The parabolic incident light flux cone F₁ may represent the area in which incident light reflects from the reflecting surface 14. The parabolic body angle θ may be defined as the angle between the centerline of the exemplary solar concentrator apparatus and an imaginary projected line from one end point of the parabolic body diameter D₁ to the focal point 35. The parabolic body angle θ may, at least partially, define the acceptance angle of solar flux of a solar concentrator apparatus, the focal point 35, and the parabolic incident light flux cone F₁.

When the parabolic body angle θ is relatively large the acceptance angle of solar flux will be less and when the parabolic body angle θ is relatively small the acceptance angle of solar flux will be greater. In some embodiments, the parabolic body angle θ may range from 30°-65°. In these embodiments, the parabolic body angles may be 30° 45° and 60°. In others it may be more or less dependent upon the particular solar concentrator apparatus and its uses.

The exemplary solar concentrator apparatus has a spherical ball lens 22 positioned within, at least a portion, of the parabolic incident light flux cone F₁. Furthermore, the spherical ball lens 22 may be in contact with and positioned directly beneath the active side of a photovoltaic module 16 (see FIG. 2). This may assist with capturing nonzero-degree incident light as illustrated in FIG. 4B. In the exemplary embodiment, the spherical ball lens 22 has a ball lens angle α that may, at least partially, define the size and overall shape of the spherical ball lens 22. Further, the ball lens angle α may also define, at least partially, the ball lens refracted area F₂. Moreover, the ball lens refracted area F₂ may fall within an active surface region defined by the photovoltaic cell diameter P₁ of a photovoltaic module 16 (see FIG. 4B and FIG. 2).

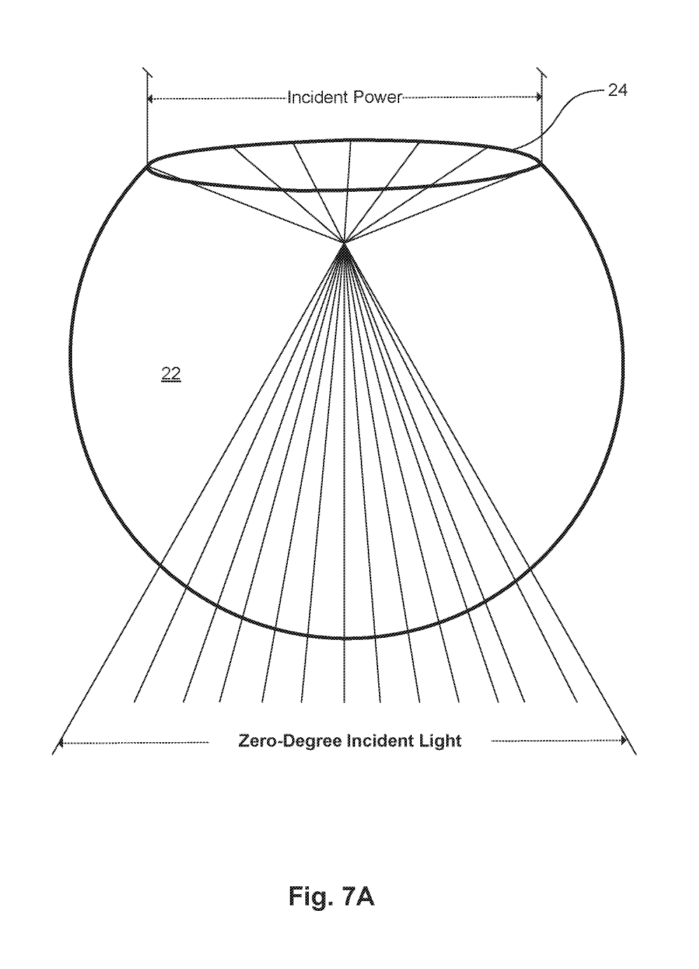

FIG. 6 is a conceptual illustration of the exemplary ball lens of FIG. 5. In the exemplary embodiment, the spherical ball lens 22 is truncated and is illustrated with a flat surface 24 nearest the upper region of the spherical ball lens 22. Further, the spherical ball lens 22 has a ball lens diameter B₁ and a ball lens angle α. The flat surface 24 of the spherical ball lens 22 may be defined, at least partially, by the ball lens angle α. For example, in an exemplary embodiment of a spherical ball lens 22 with a corresponding ball lens angle α of 90° the spherical ball lens 22 may be considered a substantially perfect hemisphere.

Moreover, FIG. 6 may be illustrative of any type of ball lens as may be disclosed throughout this application. For example, a cylindrical ball lens 12 (see FIG. 1) may be similarly defined. Further, in numerous embodiments the ball lens angle α may be within a range of 100°-140°. In other embodiments, the ball lens angle α may be greater or less than the range of 100°-140°. For example, the ball lens angle α may be within a range of 90°-170°.

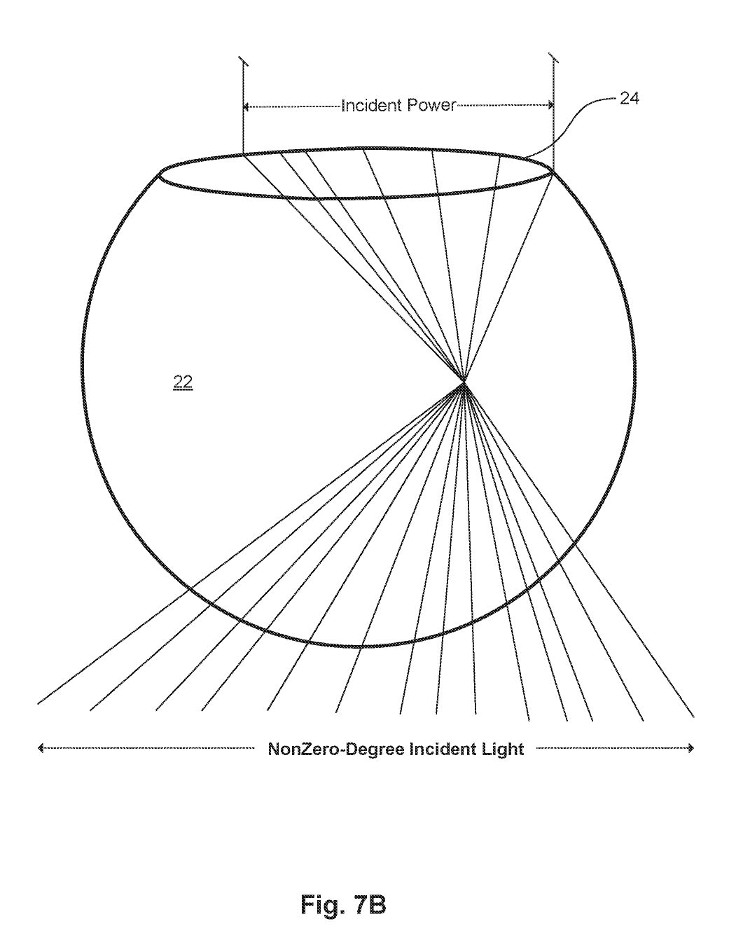

FIGS. 7A and 7B illustrate a zero-degree incident light and a nonzero-degree incident light interaction with a spherical ball lens 22. The Figs. may illustrate the relationship between light interactions and incident power of a photovoltaic module (not illustrated) that may have a substantially equal active surface area of the flat surface 24. Therefore, the light cast through the flat surface 24 may also be indicative of the light cast onto the active surface of a photovoltaic module, such as photovoltaic module 16 illustrated in FIG. 2.

In. FIG. 7A, the incident power may correspond to the entire upper flat surface 24 of the spherical ball lens 22. FIG. 7A may illustrate optimal efficiency under zero-degree incident light. However, in FIG. 7B, the incident power corresponds to a partial region of the upper flat surface 24 of the spherical ball lens 22. This may be a result of what is commonly understood as power loss due to nonzero-degree incident light.

Importantly, FIG. 7B illustrates that a significant portion of the nonzero-degree incident light that would not have fallen on the upper flat surface 24 is diffracted towards the upper flat surface 24 by the spherical ball lens 22. Therefore, because the upper flat surface 24 may correspond to an active surface of a photovoltaic module, such as photovoltaic module 16 illustrated in FIG. 2, the spherical ball lens 22 increases the incident power (efficiency) under nonzero-degree incident light.

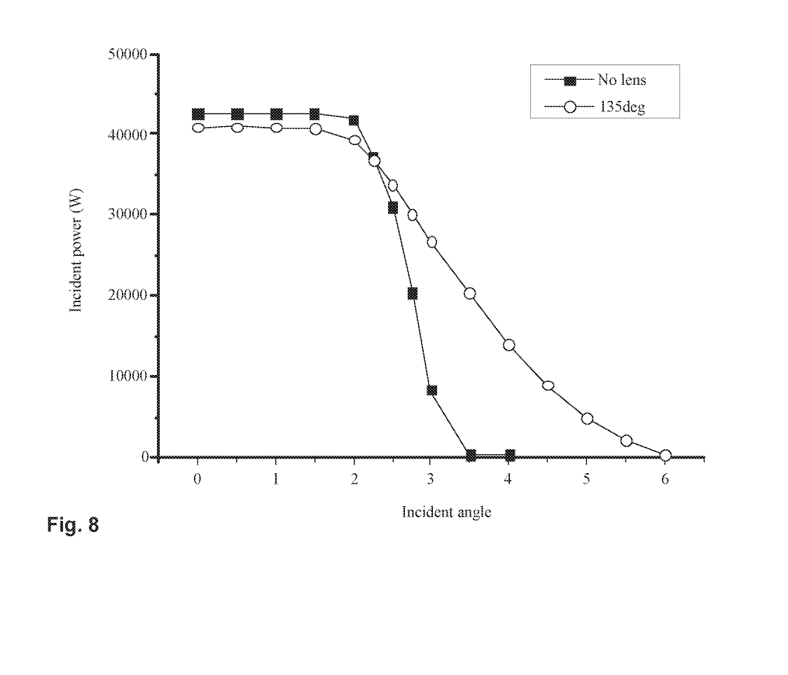

FIGS. 8-14B are graphs that illustrate various relationships between varying incident angles of solar flux and varying incident power of varying solar concentrator apparatuses. Incident power is illustrated along the Y-axis and the incident angle is illustrated along the X-axis. Incident power may correspond to the solar harvesting efficiency (electrical potential) of a solar concentrator apparatus. The incident angle may correspond to the angular difference between zero-degree incident light and the particular nonzero-degree incident light as discussed throughout this application and illustrated by FIGS. 3A, 3B, 4A, 4B, and their corresponding sections. Moreover, the area under a particular curve (lines joined by scatter points) corresponding to a particular solar concentrator apparatus is indicative of the efficiency of that particular solar concentrator apparatus.

FIG. 8 is a graph that illustrates a relationship between the incident angle of solar flux and the incident power of a solar concentrator apparatus with a ball lens angle of 135° by scatter points and lines. FIG. 8 illustrates that at a zero-degree incident angle α solar concentrator apparatus may be more efficient without a ball lens. However, the graph also illustrates that at incident angles greater than 2° the incident power is greater with a ball lens. Moreover, the area under the curve corresponding to the solar concentrator apparatus with a ball lens angle of 135° is greater than the area under the curve for the solar concentrator apparatus without the assistance of a ball lens. Therefore, for a given incident angle range a solar concentrator apparatus with a ball lens may be more efficient as indicated by the increase in incident power.

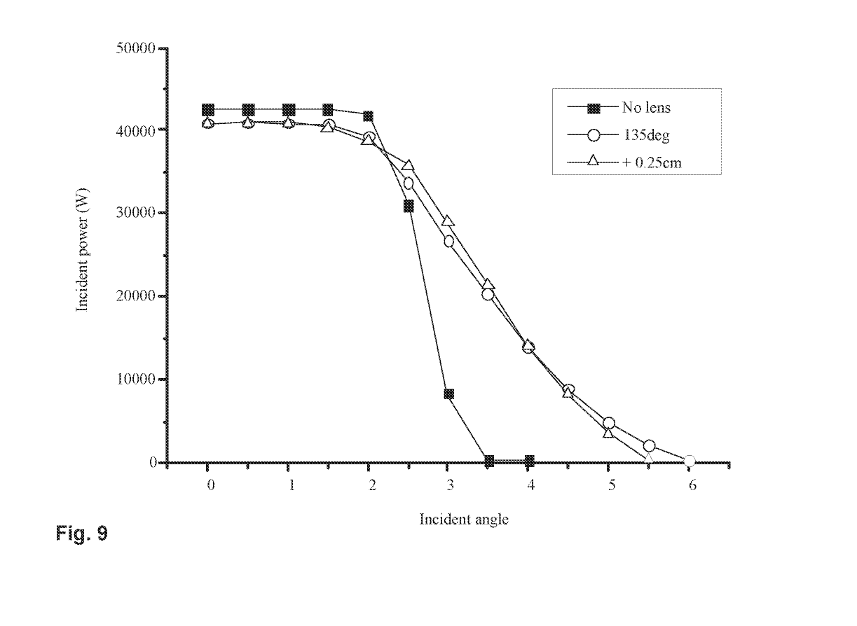

FIG. 9 is a graph that illustrates a relationship between the incident angle of solar flux and the incident power of a solar concentrator apparatus. FIG. 9 graphs three solar concentrator apparatuses by scatter points and lines. The solar concentrator apparatuses may be summarized as: without a lens, a ball lens angle of 135° (see α FIG. 6) in which the flat surface of the ball lens and photovoltaic modules are centered at the focal point of zero-degree incident light (see 35 FIG. 5), and a ball lens angle of 135° (see α FIG. 6) in which the flat surface of the ball lens and a photovoltaic module have been located 0.25 cm above the zero-degree incident light focal point (see 35 FIG. 5). In the exemplary arrangement, the flat surface of the ball lens, and the photovoltaic module are in contact with one another. Similar to FIG. 8, the area under the curves corresponding to solar concentrator apparatuses with ball lenses is greater than the area under the curve for the solar concentrator apparatus without the assistance of a ball lens.

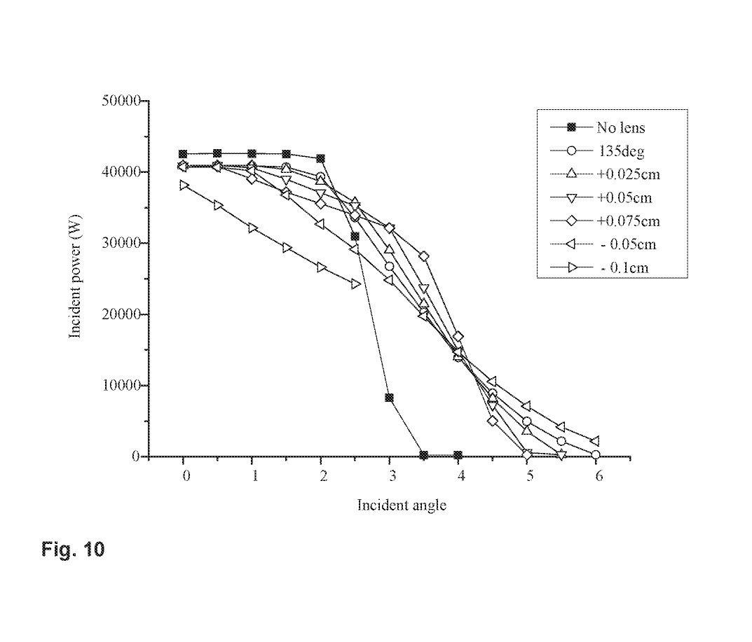

FIG. 10 is a graph that illustrates a relationship between the incident angle of solar flux and the incident power of a solar concentrator apparatus. FIG. 10 illustrates seven solar concentrator apparatuses by scatter points and lines. The solar concentrator apparatuses may be summarized as: without a lens, a ball lens angle of 135° (see α FIG. 6) in which the flat surface is centered at the focal point (see 35 FIG. 5), and five other solar concentrator apparatuses in which the flat surface of the ball lens has been located above (positive) or below (negative) the focal point (see 35 FIG. 5). In the exemplary arrangement, the flat surface of the ball lens, and the photovoltaic module are in contact with one another. Moreover, FIG. 10 illustrates exemplary reference locations and configurations of an exemplary ball lens.

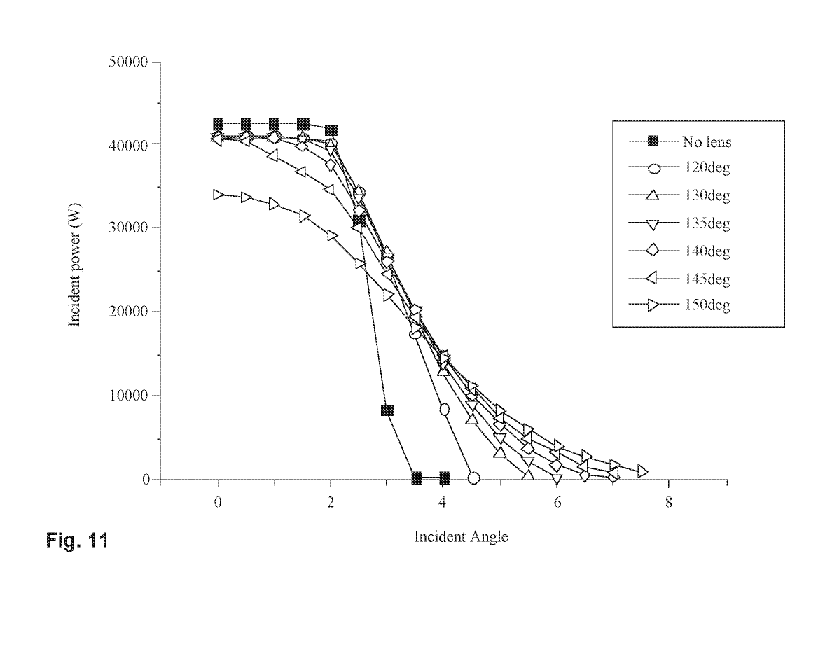

FIG. 11 is a graph that illustrates a relationship between the incident angle of solar flux and the incident power of various solar concentrator apparatuses. FIG. 11 illustrates the incident power of seven solar concentrator apparatuses with varying ball lens angles (see α FIG. 6) by scatter points and lines. The ball lens angles of the respective solar concentrator apparatuses may be summarized as ranging from 120° to 150°. Moreover, FIG. 11 illustrates exemplary ball lens angles and configurations.

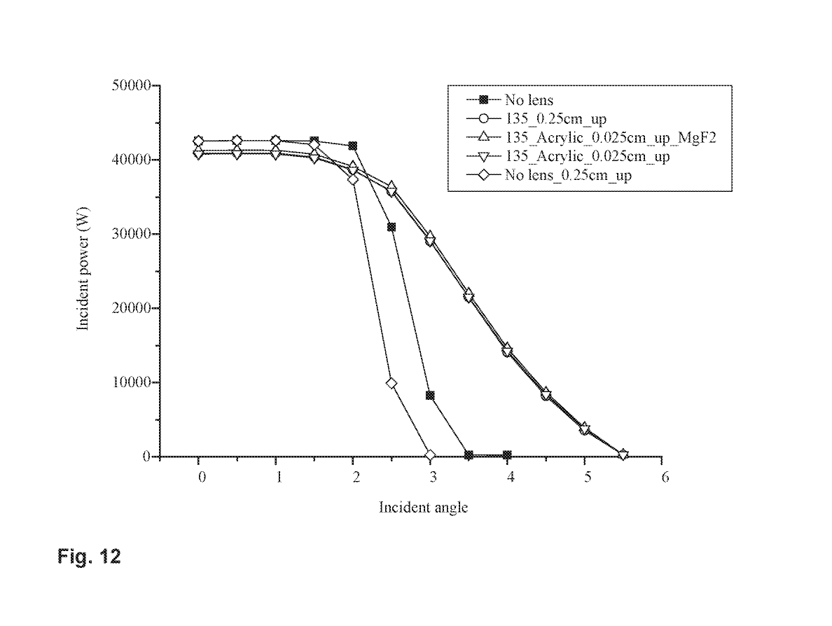

FIG. 12 is a graph that illustrates a relationship between the incident angle of solar flux and the incident power of various solar concentrator apparatuses. FIG. 12 illustrates the incident power of five solar concentrator apparatuses with ball lens angles of 135° (see α FIG. 6) by scatter points and lines. Furthermore, the five solar concentrator apparatuses may have varying ball lens compositions and coatings. Further still, the graphs indicate that an acrylic lens with a magnesium fluoride coating may have a greater efficiency than an identical lens without the surface coating. Moreover, FIG. 11 illustrates exemplary ball lens compositions and coatings.

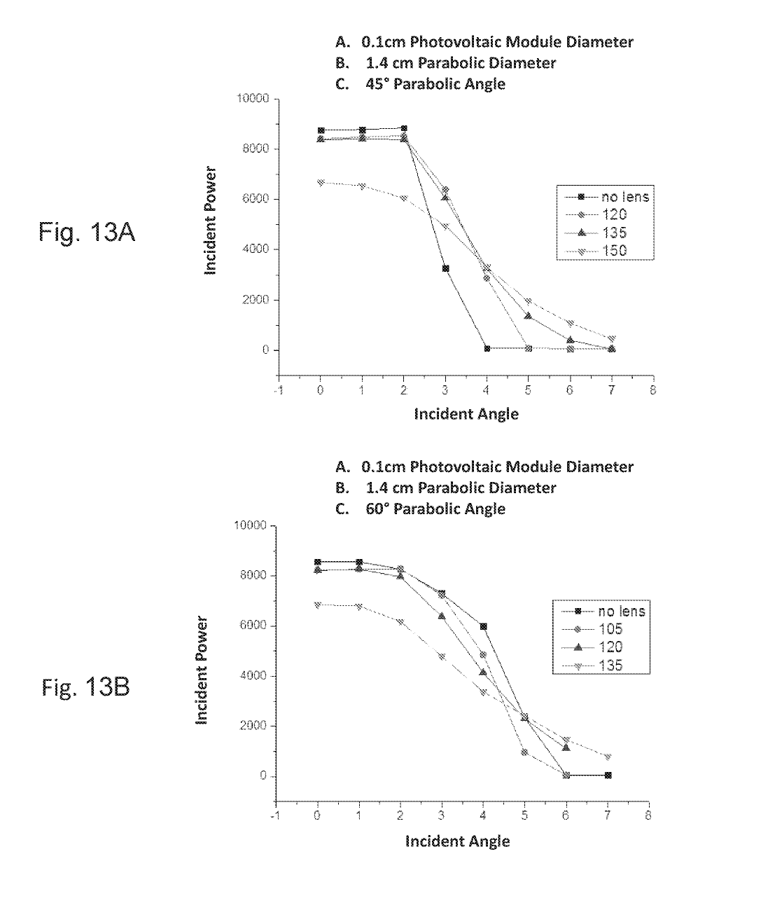

FIGS. 13A and 13B are graphs that illustrate a relationship between the incident angle of solar flux and the incident power of various solar concentrator apparatuses by scatter points and lines. FIGS. 13A and 13B may illustrate, at least partially, similar solar concentrator apparatuses but with varying parabolic angles (see θ FIG. 5). For example, FIG. 13A illustrates four solar concentrator apparatuses with a parabolic angle of 45° and FIG. 13B illustrates four solar concentrator apparatuses with a parabolic angle of 60°.

In FIG. 13A the incident angle of solar flux and the incident power of four solar concentrator apparatuses with different ball lens angles (see α FIG. 6) are illustrated. The four solar concentrator apparatuses may have the same photovoltaic module diameter of 0.1 cm (see P₁ of FIG. 5), the same parabolic body diameter of 1.4 cm (see D₁ of FIG. 5), and the same parabolic body angle of 45° (see θ FIG. 5). Moreover, FIG. 13A illustrates exemplary ball lens angles and configurations.

In FIG. 13B the incident angle of solar flux and the incident power of four solar concentrator apparatuses with different ball lens angles (see α FIG. 6) are illustrated. The four solar concentrator apparatuses may have the same photovoltaic module diameter of 0.1 cm (see P₁ of FIG. 5), the same parabolic body diameter of 1.4 cm (see D₁ of FIG. 5), and the same parabolic body angle of 60° (see θ FIG. 5). Moreover, FIG. 13A illustrates exemplary ball lens angles and general configurations of solar concentrator apparatuses.

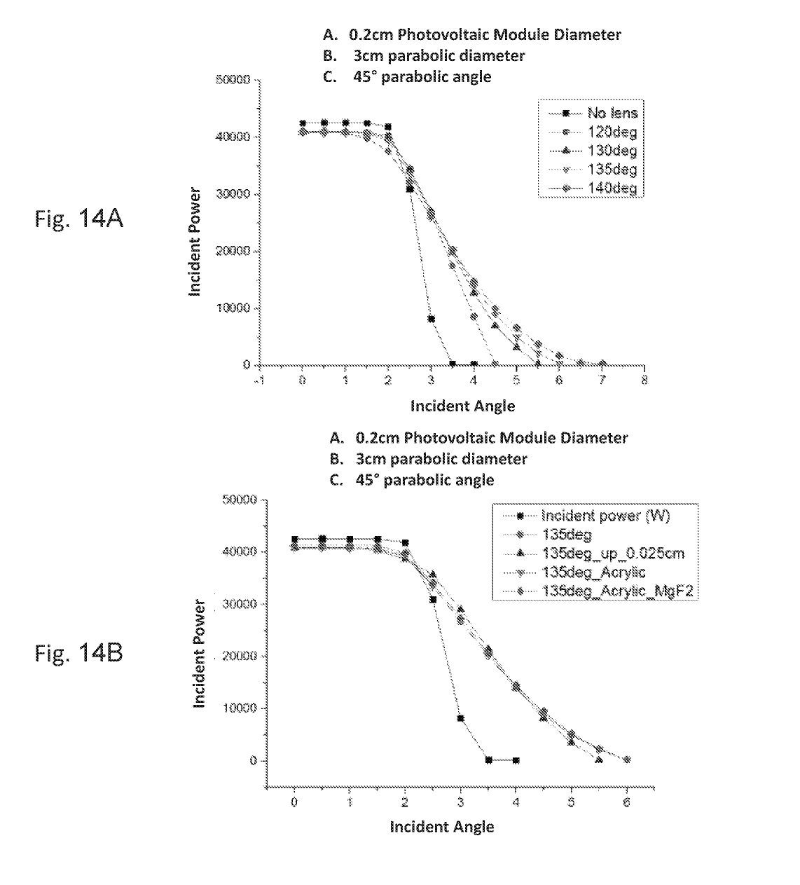

FIGS. 14A and 14B are graphs that illustrate a relationship between the incident angle of solar flux and the incident power of various solar concentrator apparatuses by scatter points and lines. FIGS. 14A and 14B may illustrate, at least partially, similar solar concentrator apparatuses but with varying ball lens angles (see a FIG. 6) and ball lens surface coatings (see 28 FIG. 2).

In FIG. 14A the incident angle of solar flux and the incident power of five solar concentrator apparatuses with different ball lens angles (see α FIG. 6) are illustrated. The five solar concentrator apparatuses may have the same photovoltaic module diameter of 0.2 cm (see P₁ of FIG. 5), the same parabolic body diameter of 3.0 cm (see D₁ of FIG. 5), and the same parabolic body angle of 45° (see θ FIG. 5). Moreover, FIG. 14A illustrates exemplary ball lens angles and general configurations of solar concentrator apparatuses.

In FIG. 14B the incident angle of solar flux and the incident power of four solar concentrator apparatuses with different ball lens angles (see α FIG. 6) and surface coatings (see 28 FIG. 2) are illustrated. The various solar concentrator apparatuses may have the same photovoltaic module diameter of 0.2 cm (see P₁ of FIG. 5), the same parabolic body diameter of 3.0 cm (see D₁ of FIG. 5), and the same parabolic body angle of 45° (see θ FIG. 5). Moreover, FIG. 14A illustrates exemplary ball lens angles, ball lens surface coatings, and general configurations of solar concentrator apparatuses.

FIGS. 8-14B illustrate numerous embodiments and conceptual concepts that correlate to the heightened efficiency of using a ball lens in conjunction with a parabolic concentrator. The particular embodiments disclosed should not be construed to indicate that any particular solar concentrator is more efficient, less efficient, a preferred embodiment, or a less preferred embodiment. Rather, the illustrations must be viewed with an understanding that they are exemplary in nature and aim only to illustrate that under select circumstances various embodiments may be correlated with various incident power ranges. Moreover, the totality of disclosed embodiments should be understood to convey the fact that each particular embodiment has distinct advantages and that this disclosure contemplates all of the disclosed embodiments, their equivalents, in combination, and in part.

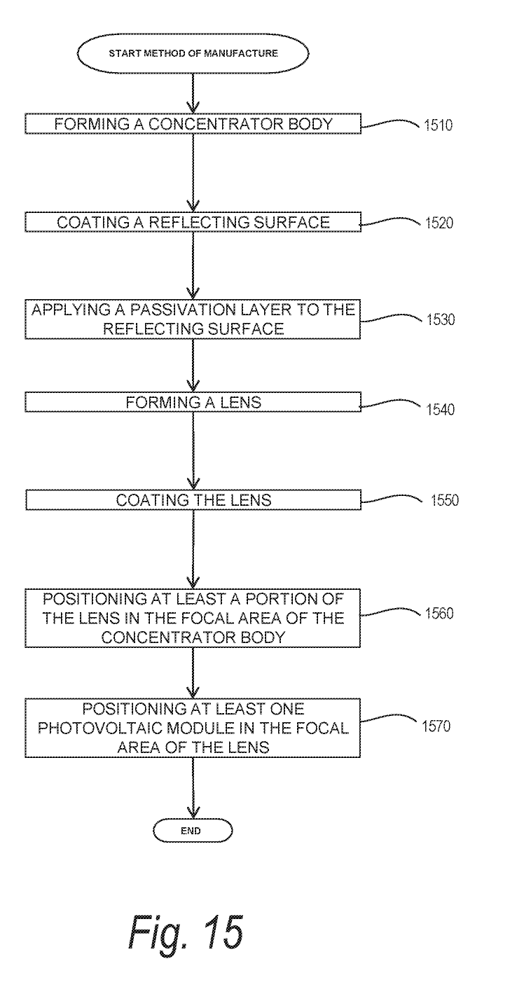

FIG. 15 is an exemplary flow chart of a method of manufacture of a solar concentrator apparatus. First, at step 1510 a concentrator body may be formed. The concentrator body may be, for example, a trough parabolic body as illustrated in FIGS. 1A and 1B or it may be a dish parabolic body as illustrated in FIG. 2. In some embodiments, the concentrator body may be formed by thermoplastic material or a metallic material and it may utilize a mold. For example, a thermoplastic material may be formed into a parabolic shape by applying heat and vacuum principles or it may be injection molded.

Next, at step 1520 a reflective surface may be coated to the parabolic body as illustrated by FIGS. 1A, 1B, and 2. The coated reflective surface may be comprised of any reflective material or reflective film. For example, silver may be coated by vacuum thermal deposition in which a silver source is heated and is allowed to evaporate on the target surface. In other embodiments, Ebeam deposition may heat a silver source that is allowed to evaporate on the target surface. In other embodiments still, sputtering may also be used in which high energy Argon beams are used to heat the silver source but do not react with it or at least react insubstantially. In other embodiments, the reflective surface may be a reflecting film that is adhered to the target surface. For example, a 200-800 nm thick silver film. However, the thickness of the film and its chemical composition is intended to cover other equivalents.

Next, at step 1530 a passivation layer may optionally be applied to the target reflective surface. The passivation layer may be a transparent, wide bandgap material that does not absorb significant amounts of sunlight. For example, silicon dioxide may be an appropriate material in at least one embodiment as it may prevent the silver from oxidizing.

Next, at step 1540 a lens may be formed. The lens may be a cylindrical ball lens as illustrated in FIGS. 1A and 1B or it may be a spherical ball lens as illustrated in FIG. 2. The lens may be formed from silica, silicon, silicon dioxide, or any substantially similar chemical composition. For example, a crystalline silica such as sand or quartz. In other embodiments, the lens may be formed from an acrylic compound. In some embodiments, the lens may be formed by grinding down a spherical lens to form a lens with a flat surface or the lens may be formed from a mold. An exemplary lens with a flat surface is illustrated in FIG. 6. Next, at optional step 1550 the lens may be coated. For example, a magnesium fluoride composition may be coated on the surface of the lens. The coating may be advantageous as it may reduce the reflection of light along the lens surface thereby increasing the amount of light that enters the lens.

Next, at least a portion of the lens may be positioned within a incident light flux cone of the concentrator body. In some embodiments, the lens may be positioned within the focal point of the concentrator body as illustrated by FIG. 5. In other embodiments, the lens may be slightly above or below the focal point. Next, at least one photovoltaic module may be positioned with the refracted area of the lens. In some embodiments, the photovoltaic module may have an active surface with a surface area that is substantially equal to the surface area of the flat surface of a lens. Furthermore, in some embodiments, the photovoltaic module may be in contact with the flat surface of the lens. However, the photovoltaic module may be of a larger size and need not always be in contact with the lens.

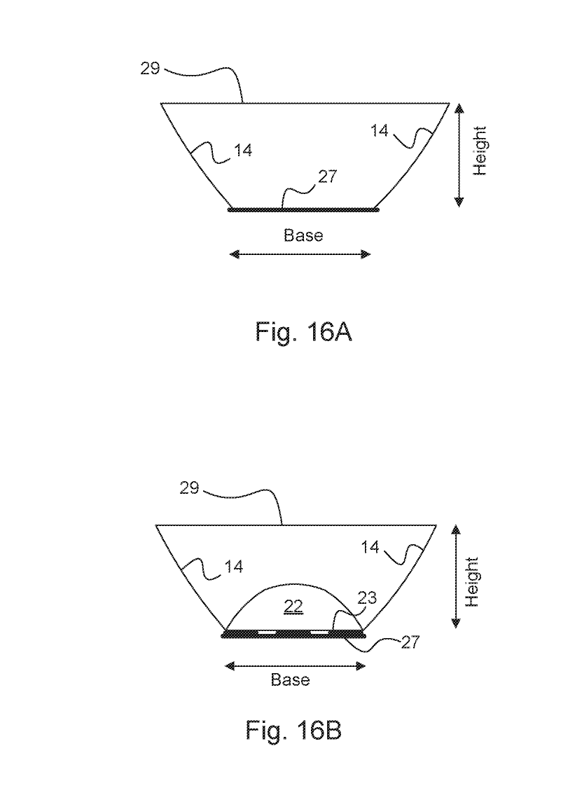

The ball lens concepts described herein may also be used with compound parabolic concentrators. FIGS. 16A and 16B are elevation views of compound parabolic concentrator apparatuses with and without a hemispherical ball lens, respectively. In FIG. 16A a compound parabolic concentrator body 29 has a reflecting surface 14. In the exemplary embodiment, the compound parabolic concentrator body 29 has a low profile and the reflecting surface 14 is located on the inside of the compound parabolic concentrator body 29. This may increase the overall angular acceptance and concentration factor of solar flux. A particular advantage of the low profile compound concentrator is that it has a wide angular acceptance which may be ideal for non-tracking solar installations such as rooftops.

Furthermore, in at least one exemplary embodiment, the base of the parabolic concentrator body 29 may be 40 mm and the height of the parabolic concentrator body 29 may be 30 mm. In other embodiments, the ratio may be similar to 4/3 when comparing the base to the height. In other embodiments still, the base dimension and the height dimension may be different.

The solar concentrator body 29 and reflecting surface 14 may reflect light toward the photovoltaic module 27. In some embodiments, the photovoltaic module 27 may be a gallium arsenide (GaAs) photovoltaic module. In other embodiments, the photovoltaic module may be a silicon photovoltaic module. In other embodiments still, the photovoltaic module 27 may be coupled to the compound parabolic concentrator body 29. However, the photovoltaic module 27 may simply be in contact with or adjacent to the base of the compound parabolic concentrator body 29.

In FIG. 16B a compound parabolic concentrator apparatus with a spherical ball lens is illustrated. The compound parabolic concentrator apparatus may be similar to the embodiment of FIG. 16A with the added spherical ball lens 22 and index matching layer 23. The index matching layer 23 may have a lower refractive index compared to the photovoltaic module 27 and a higher refractive index than the spherical ball lens 22. Furthermore, the index matching layer 23 may reduce reflection and increase the efficiency of the compound parabolic concentrator apparatus. For example, by placing a material that has a lower refractive index compared to the photovoltaic module 27 and a higher refractive index than the spherical ball lens 22, the index matching layer 23 may have a total internal reflection at both sides, upwards and downwards, thereby trapping light until it gets to the photovoltaic module 27 within a certain angle.

In the exemplary embodiment of FIG. 16B, the spherical ball lens 22 is hemispherical. However, in other embodiments the spherical ball lens 22 may have alternate ball lens angles (see α of FIG. 6) as described throughout herein and particularly with the conceptual underpinnings of FIG. 6.

In an exemplary embodiment, the spherical ball lens 22 may be coupled to the base of the compound parabolic concentrator body 29, index matching layer 23, and the photovoltaic module 27. In other embodiments, the aforementioned components may be in contact with or adjacent to one another. The inclusion of the spherical ball lens 22 at the base of the compound parabolic concentrator body 29 may be effective in enhancing the absorption of nonzero-degree incident light. For example, light entering the compound parabolic concentrator apparatus from an oblique angle such as when the sun approaches the horizon during sunset. Furthermore, the inclusion of the index matching layer 23 between the spherical ball lens 22 and the photovoltaic module 27 may be advantageous as it may trap light until it gets to the photovoltaic module 27 within a certain angle.

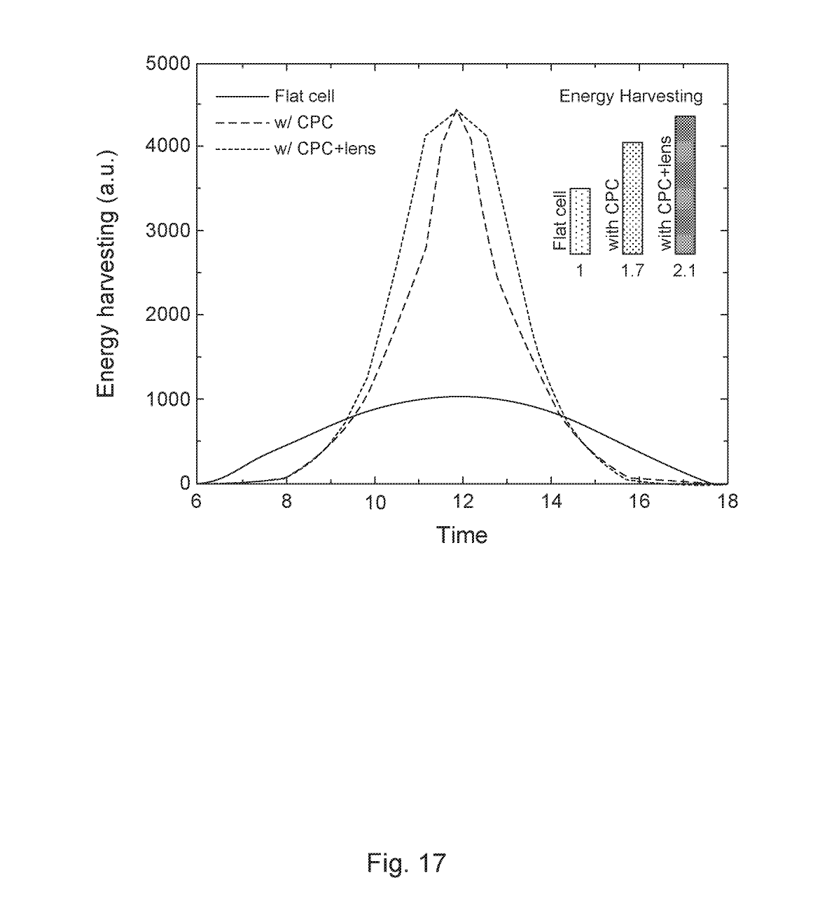

FIG. 17 is a graph that illustrates the energy harvesting potential of various compound solar concentrator apparatuses. The energy harvesting potential may be proportional to the photovoltaic modules 27 efficiency. FIG. 17 illustrates the differences in harvesting potential of three non-tracking photovoltaic modules. A flat cell without a compound solar concentrator apparatus has a base-line harvesting potential of one. The harvesting potential of the flat cell may be a base line reference value. The compound solar concentrator apparatus and photovoltaic module without the hemispherical lens has an energy harvesting potential of 1.7. The compound solar concentrator apparatus and photovoltaic module with the hemispherical ball lens has an energy harvesting potential of 2.1. Therefore, in non-tracking situations, a compound solar concentrator with hemispherical ball lens may have greater than double the energy harvesting potential of a simple flat cell.

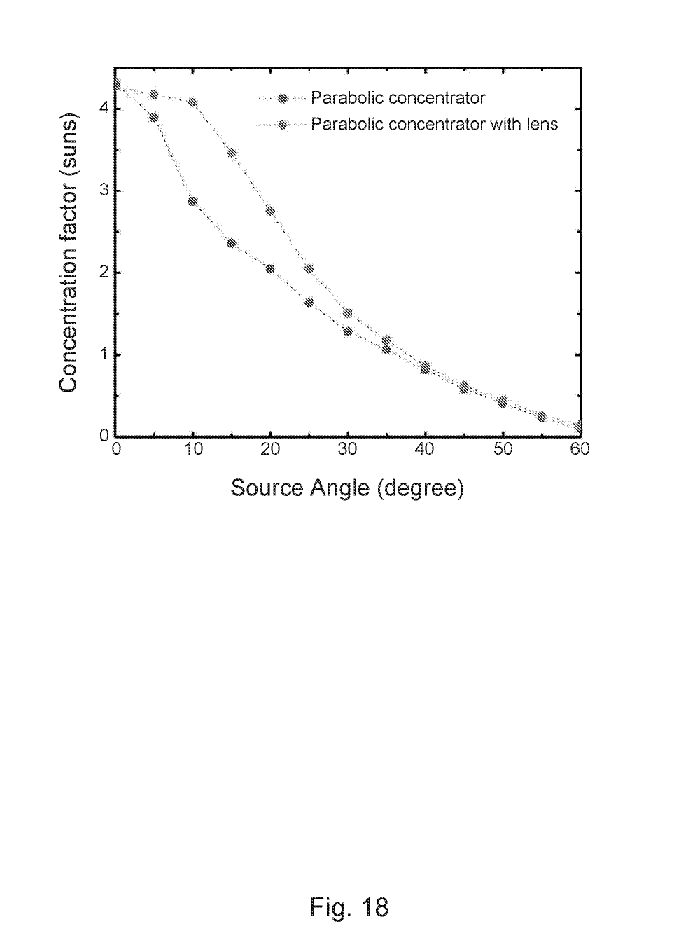

FIG. 18 is a graph that illustrates the concentration factor of compound parabolic concentrators with and without a hemispherical ball lens, respectively. The uppermost line is representative of the concentration factor of a compound parabolic concentrator apparatus with a hemispherical lens while the lowermost line is representative of the concentration factor of a compound parabolic concentrator apparatus without a hemispherical lens. As illustrated by FIG. 18 the two embodiments have significantly different concentration factors between source angles in the range of 10°-35°. Therefore, at oblique incident angles between 10°-35° the hemispherical lens shows significant improvements in efficiency. Furthermore, the area underneath the respective lines may be illustrative of the total solar harvesting potential of each configuration. Therefore, the compound parabolic concentrator apparatus with a hemispherical lens may have a greater total solar harvesting potential.

While illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application, which examples are to be construed as non-exclusive. It is intended, therefore, that the specification and examples be considered as example only, with a true scope and spirit being indicated by the following claims and their full scope of equivalents.

What is claimed is:

1. A solar concentrator apparatus comprising:
a parabolic body having a reflecting surface to receive incident light;
wherein the parabolic body and reflecting surface have an incident light flux cone; and
a ball lens positioned within at least a portion of the incident light flux cone,
wherein the ball lens has a refracted area and is configured to direct at least a portion of the incident light that is reflected by the reflecting surface of the parabolic body into the refracted area.

2. The solar concentrator apparatus of claim 1, comprising at least one photovoltaic module positioned to receive at least a portion of the light that is directed by the ball lens into the refracted area.

3. The solar concentrator apparatus of claim 2, wherein at least part of the incident light flux cone is outside of the active surface of the at least one photovoltaic module and the refracted area is substantially on the surface of the at least one photovoltaic module.

4. The solar concentrator apparatus of claim 1, wherein the ball lens has a lens angle of 90-170 degrees.

5. The solar concentrator apparatus of claim 1, wherein the ball lens has a lens angle of 100-140 degrees.

6. The solar concentrator apparatus of claim 5, wherein the ball lens has a substantially flat surface in contact with a photovoltaic cell.

7. The solar concentrator apparatus of claim 1, wherein the ball lens comprises fused silica.

8. The solar concentrator apparatus of claim 7, wherein the ball lens comprises a surface coating.

9. The solar concentrator apparatus of claim 8, wherein the surface coating comprises Magnesium Fluoride.

10. The solar concentrator apparatus of claim 1, wherein the reflecting surface comprises Silver.

11. The solar concentrator apparatus of claim 10, wherein the reflecting surface comprises a passivation layer.

12. The solar concentrator apparatus of claim 11, wherein the passivation layer comprises silicon dioxide.

13. The solar concentrator apparatus of claim 1 wherein the reflecting surface is a film having a thickness ranging from 250-750 nm.

14. The solar concentrator apparatus of claim 4, wherein the parabolic body has a parabolic angle of 40-65 degrees.

15. The solar concentrator apparatus of claim 14, wherein the parabolic body is a dish parabolic body.

16. The solar concentrator apparatus of claim 15, wherein the ball lens is a substantially spherical ball lens.

17. The solar concentrator apparatus of claim 14, wherein the parabolic body is a trough parabolic body.

18. The solar concentrator apparatus of claim 17, wherein the ball lens is a cylindrical ball lens.

19. A method of manufacturing a parabolic solar concentrator and lens pair comprising:
forming a concentrator body having a corresponding incident light flux cone;
coating a reflecting surface to the concentrator body;
forming a lens with a corresponding refracted area;
positioning at least a portion of the lens within the incident light flux cone; and
positioning at least a portion of at least one photovoltaic module within the refracted area.

20. The method of claim 19, comprising the step of applying a passivation layer to the reflecting surface.

21. The method of claim 19, comprising the step of coating the lens.

22. A compound parabolic concentrator apparatus comprising:
a compound parabolic concentrator body having a reflecting surface,
a spherical ball lens positioned within a base region of the compound parabolic concentrator body; and
at least one photovoltaic module positioned beneath the spherical ball lens.

23. The compound parabolic concentrator apparatus of claim 22, wherein the photovoltaic module, spherical ball lens, and compound parabolic concentrator body are fixedly attached.

24. The compound parabolic solar concentrator apparatus of claim 22, wherein the spherical ball lens has a substantially flat surface adjacent to the photovoltaic cell.

25. The compound parabolic solar concentrator apparatus of claim 24, wherein the spherical ball lens is a hemispherical ball lens.

26. The compound parabolic solar concentrator apparatus of claim 22, wherein the photovoltaic module is a gallium arsenide (GaAs) photovoltaic module.

27. The compound parabolic solar concentrator apparatus of claim 22, wherein a ratio between the base region and a height of the compound parabolic concentrator body ranges from (3/2)-(5/4).

28. The compound parabolic solar concentrator apparatus of claim 22, wherein a ratio between the base region and a height of the compound parabolic concentrator body is (4/3).

29. The compound parabolic solar concentrator apparatus of claim 22, wherein the base region is approximately 40 mm in length and a height of the compound parabolic concentrator body is approximately 30 mm in length.
